(19) United States
(12) Patent Application Publication
(10) Pub. No.: US 2023/0034507 A1
(43) Pub. Date: Feb. 2, 2023

(54) FORMATION STIMULATION WITH ACID ETCHING MODEL

(71) Applicant: SCHLUMBERGER TECHNOLOGY CORPORATION, Sugar Land, TX (US)

(72) Inventors: Rostislav Vladimirovich ROMANOVSKII, Novosibirsk (RU); Denis Viktorovich BANNIKOV, Koltsovo (RU); Denis Yurievich EMELYANOV, Koltsovo (RU); Olga Vladimirovna NEVVONEN, Koltsovo (RU); Galina Gennadievna PETUKHOVA, Moscow (RU); Alexey Vladimirovich ALEKSEEV, Novosibirsk (RU); Dmitry Sergeevich KUZNETSOV, Novosibirsk (RU)

(21) Appl. No.: 17/757,591

(22) PCT Filed: Dec. 19, 2019
(86) PCT No.: PCT/RU2019/000981

§ 371 Date: Jun. 17, 2022

(51) Int. Cl. E21B 43/27; E21B 43/267; E21B 49/00

(52) U.S. Cl. CPC E21B 43/27; E21B 43/267; E21B 49/00; E21B 2200/20

(57) ABSTRACT

A method of stimulating fluid production from a well includes defining a candidate stimulation treatment including injection of a slurry comprising acid and proppant, based on measurements of the formation. Fracture propagation and fluid transport in the formation are simulated using particle-in-cell techniques. Etching of rock by the injected acid is simulated. Rock compaction is simulated, including compaction around etched and propped portions of a fracture. A predicted fluid conductivity for acid-stimulated fracture is calculated based on the simulation of fracture geometry and a final stimulation treatment is defined based on the predicted fluid conductivity. An acid-proppant slurry is injected into the formation according to the final stimulation treatment.

### FIELD

This relates to hydrocarbon production, and in particular to hydrocarbon production using well stimulation techniques.

### BACKGROUND

Hydrocarbons such as oil and natural gas are generally extracted by drilling wells into hydrocarbon-bearing geological formations. Extraction of hydrocarbons in this manner may be referred to as “production”.

For some wells and formations, the quantity of hydrocarbons which may be produced from a reservoir, or the rate at which such hydrocarbons may be produced, may be improved by stimulation of the well or reservoir using various techniques. Example techniques include high-pressure injection of fluids such as water, gels, acids or slurries including fibers or proppants. This practice is generally referred to as hydraulic fracturing and it benefits from a high conductivity of fractures remained after fracture closing.

Typically, an aim of such stimulation is to increase the conductivity of the formation to hydrocarbon fluids, such that fluids can more easily pass through the formation to the wellbore for production. For example, pressurized fluid may create and physically widen fractures in the formation, which may be held open by proppant. Similarly, acidic fluids may etch surfaces in the formation, creating additional clearance for fluid flow.

Stimulation treatments may be designed and performed with the aid of simulations to predict the effects of a particular treatment. An example transport simulation technique is disclosed in Mao, S., et al., An Efficient Three-dimensional Multiphase Particle-in-cell Model for Proppant Transport in the Field Scale, Unconventional Resources Technology Conference 462, 22-24 Jul. 2019. Mao et al. describe simulation of placement of proppant particles in three dimensions. However, the disclosed technique does not account for acid etching, consumption of acid or rock bending.

### SUMMARY

A method of stimulating fluid production from a well in a formation comprises: obtaining measurements of formation characteristics; defining a plurality of candidate stimulation treatments comprising injection of an acidic fluid; for each one of the candidate stimulation treatments: based on the measurements, simulating fracture propagation in the formation, induced by pressurized fluid injection, the simulating comprising defining grid cells representing a fracture; simulating transport of an injected acidic fluid through the formation, wherein the simulating transport comprises tracking movement of units of the acidic fluid between ones of the grid cells; simulating etching of rock in the fracture to obtain a model of a an etched fracture comprising a plurality of rock pillars representing non-uniform etching in the grid cells; simulating compaction of rock in the formation based on an etched fracture size for each one of the grid cells, to obtain a compacted fracture size associated with each one of the grid cells; and calculating a predicted fluid conductivity associated with the candidate stimulation treatment, based on the simulating; defining a final stimulation treatment based on one of the candidate stimulation treatments and the predicted fluid conductivity; and injecting the acidic fluid into the formation according to the final stimulation treatment.

A system for stimulating fluid production from a well in a formation comprises: a plurality of sensors for measuring characteristics of the formation; a computing device comprising a processor and a computer-readable storage; computer-readable instructions stored on the computer-readable storage, for simulating a plurality of candidate stimulation treatments comprising injection of an acidic fluid, the computer-readable instructions comprising: a fracture propagation model for simulating fracture propagation induced by pressurized fluid injection in the formation, by defining grid cells representing a fracture; a transport model for simulating transport of an injected acidic fluid through the formation by tracking movement of units of the acidic fluid between ones of the grid cells; an etching model for simulating etching of rock in the fracture to obtain a representation of an etched fracture comprising a plurality of rock pillars from non-uniform etching in the grid cells; a rock-bending model for simulating compaction of rock in the formation based on an etched fracture size for each one of the grid cells, to obtain a compacted fracture size associated with each one of the grid cells; instructions for evaluating a predicted fluid conductivity associated with each of the candidate stimulation treatments, based on the simulating, wherein one of the candidate simulation treatments is defined as a final simulation treatment in response to the predicted fluid conductivity meeting performance criteria.

A method of stimulating fluid production from a well in a formation comprises: obtaining measurements of formation characteristics; defining a candidate stimulation treatment comprising injection of a slurry comprising acidic fluid and proppant; for each of the plurality of candidate stimulation treatments: based on the measurements, simulating fracture propagation and fluid-proppant slurry transport in the formation using a Particle-in-Cell method; simulating etching of rock in the fracture to obtain a model of a an etched fracture comprising a plurality of rock pillars representing non-uniform etching in the grid cells; simulating compaction of rock in the formation based on an etched fracture size for each one of the grid cells, to obtain a compacted fracture size associated with each one of the grid cells; calculating a predicted fluid conductivity for each of candidate stimulation treatments; defining a final stimulation treatment based on one of the candidate stimulation treatments and the predicted fluid conductivity; and injecting the acidic fluid with proppant into the formation according to the final stimulation treatment.

### BRIEF DESCRIPTION OF DRAWINGS

In the figures, which depict example embodiments:

FIG. 1 is a schematic view of a geological formation with a wellbore and a fracture;

FIGS. 2A-2B are block diagrams depicting components of a control system and a simulation server;

FIG. 3 is a block diagram showing components of a numerical model for the process of FIG. 2;

FIG. 4 is a schematic diagram showing a fracture model;

FIG. 5 is a block diagram showing components of a placement model using particle-in-cell techniques for the process of FIG. 2;

FIG. 6 is a schematic diagram showing a particle record of the placement model of FIG. 5;

FIG. 7 is a schematic diagram showing a cell record with values defining a velocity field;

FIG. 8 is a block diagram showing components of a conductivity model for the process of FIG. 2;

FIG. 9 is a schematic diagram depicting etching of walls of a fracture within the formation of FIG. 1;

FIG. 10 is a schematic diagram depicting calculation of rock pillar width;

FIG. 11 is a schematic diagram depicting definition of rock pillars;

FIG. 12 is a schematic diagram depicting an aperture definition;

FIG. 13 is a schematic diagram depicting a compacted fracture;

FIG. 14 is a schematic diagram depicting calculation of rock pillar width with proppant;

FIG. 15 is a schematic diagram depicting definition of rock pillars with proppant;

FIG. 16 is a schematic diagram depicting an aperture definition;

FIG. 17 is a schematic diagram depicting a compacted fracture; and

FIG. 19 is a flow chart depicting a process for a stimulation operation.

### DETAILED DESCRIPTION

The present disclosure provides methods and apparatus for stimulating production from a formation such as a hydrocarbon-bearing formation. Such stimulation is effected by injection of pressurized fluid into the formation through a wellbore. The pressurized fluid may include proppant, acid, or both.

The fluid is injected at a pressure sufficient to cause shifts within the formation. For example, the pressurized fluid may widen existing fractures or induce new fractures within the formation. Once the pressure is relieved, stress in the formation, referred to as closure stress tends to urge rock back to its original position. Proppant particles in the injected fluid may become lodged between adjacent rock surfaces at a fracture, so that the aperture between rock surfaces is held open against closure stress. This may be referred to as a propped fracture.

Acid in the injected fluid may also provide additional clearance between rock surfaces in the formation, for example, by etching the surfaces so that additional space remains after the fracturing pressure is relieved.

The effectiveness of these mechanisms and interaction between these mechanisms may depend on numerous factors, such as the type of rock and hydrocarbons in the formation, rock porosity, and pre-existing fracture geometry. Such factors, may for example, impact the flow of fracturing fluid through the formation, movement of proppant within the injected fluid, consumption of acid and extent of etching, closure stress and propped aperture size.

The success of a stimulation may be assessed in terms of the increase in conductivity of the formation or production from the formation, relative to the cost of the stimulation.

Therefore, in disclosed examples, a simulation is performed as part of a stimulation operation, in order to identify advantageous parameters for stimulation. Such parameters may include one or more injection locations, through which pressurized fluid will pass into the formation, injection pressures, pumping schedules, and fluid and proppant quantity and composition, among other factors.

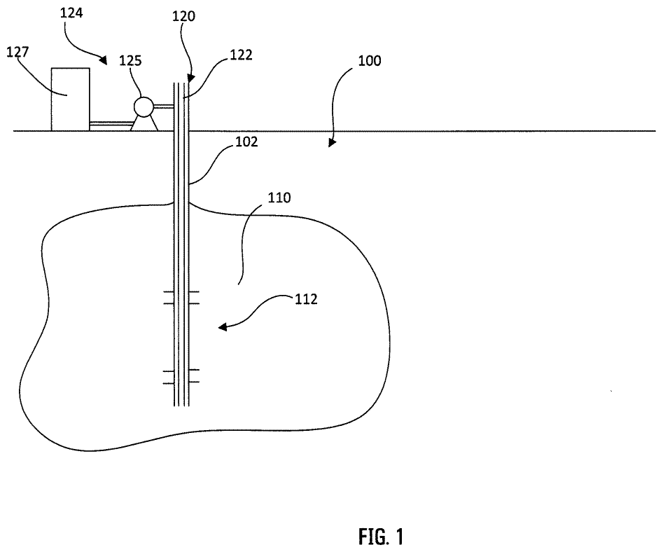

FIG. 1 is a simplified schematic view of a hydrocarbon-bearing formation 100, with a well bore 102 drilled within the formation for production of hydrocarbons.

Hydrocarbons within the formation 100 may pass through the formation to the well bore 102 through flow passages such as pores or fractures. The propensity of the formation to permit flow of hydrocarbons may be referred to as conductivity.

Pressurized fluid may be injected into formation 100 through wellbore 102. Such injection may cause the formation to shift and may induce fracturing. This may, in turn, lead to increased conductivity of the formation, and improved hydrocarbon production. This process is referred to as hydraulic fracturing.

As shown in FIG. 1, a fracture network exists within formation 100, surrounding wellbore 102. The fracture network includes fractures 110, which may be naturally occurring or artificially induced, e.g. by hydraulic fracturing. The fracture network may be approximately uniform, or may include concentrations of fractures 110 at one or more locations within formation 100.

Hydrocarbons may likewise be distributed uniformly or non-uniformly throughout the formation 100. For example, hydrocarbons may be concentrated in one or more regions of formation 100.

Hydrocarbons and other fluids may flow through fractures 110 in formation 100, as indicated by arrows 112. Fluid flow through the formation may be dependent, for example, on the number and size of fractures 110, distribution of fluids relative to the fractures, and pressure gradients within the formation.

Wellbore 102 extends from the surface into formation 100. A wellhead 120 is positioned at the surface, and a tubing string 122 extends from the wellhead 120, downwardly within wellbore 102 along the length of the wellbore.

A pumping system 124 is provided at the surface, in communication with tubing string 122 by way of the wellhead 120, for pumping fluid under pressure into tubing string 122.

Tubing string 122 has one or more injection ports 126 positioned along its length. Injection ports 126 are openings in at which the interior of tubing string 122 communicates with formation 100, so that pressurized fluid can pass from tubing string 122 into formation 100. Injection ports 126 may be controllable. That is, injection ports may be selectively opened, such that injection of pressurized fluid into formation 100 need not simultaneously occur at all ports 126.

Pumping system 124 includes one or more surface pumps 125 and one or more fracturing fluid reservoirs 127. Components of pumping system 124 may be positioned on trucks or other movable platforms.

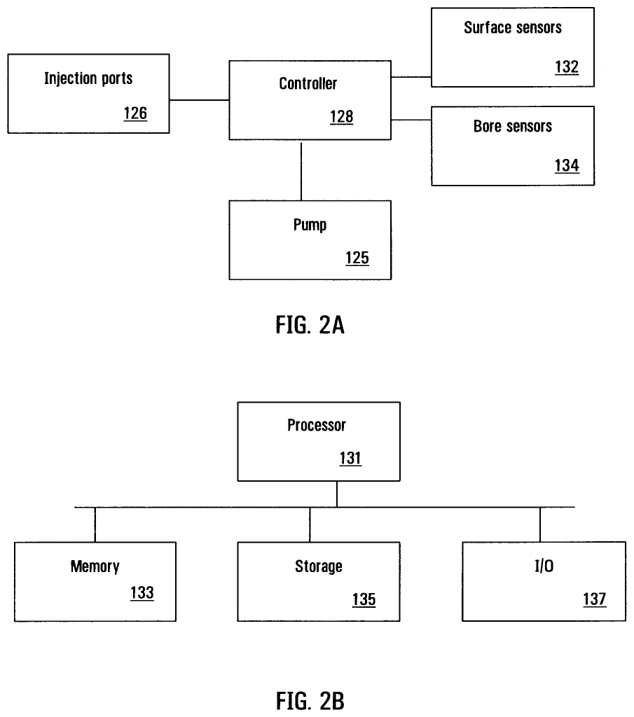

A control system is located at the surface and is operable to control pumping system 124 and to selectively open ports 126. Components of the control system are depicted in FIG. 2A. The control system includes a controller in communication with pumping system 124 and injection ports 126. Controller 128 may, for example, control the operating speed and output pressure of pump 124, and may remotely trigger opening of ports 126. The control system may further include one or more sensors for observing characteristics of formation 100 before, during and after a stimulation operation. Such sensors may include, for example, surface-mounted sensors 132 such as seismic or vibration sensors, and a plurality of bore sensors 134. Bore sensors 134 may be placed within wellbore 102 or within core sample bores drilled in the vicinity of formation 100. Sensors 132, 134 may include sonic sensors, seismic sensors, pressure sensors, and the like.

Data recorded using the control system may be used to construct a computerized model of formation 100 for simulation in order to design a stimulation operation.

Aspects of any of wellbore 102, tubing string 122, ports 126, pumping system 124 and control system 128, as well as parameters of a stimulation performed on formation 100, may be constructed in accordance with simulations. Such simulations may allow refinement of physical and process design, to help ensure satisfactory performance of the ultimate stimulation operation. For example, design with simulations may allow for a stimulation to be conducted efficiently or may aid in ensuring high production from well 102.

FIG. 2B depicts a computing device for simulating a stimulation operation. The computing device includes a processor 131, memory 133, persistent storage 135, and one or more input/output (I/O) devices 137.

Processor 131 may be, for example, a general-purpose processor such as an Intel or AMD processor based on the x86 instruction set, or a processor based on the ARM instruction set. Other possibilities will be apparent to skilled persons.

Processor 131 executes instructions stored at persistent storage 135 to simulate a stimulation operation as described in greater detail below. Data may be received from sensors 132, 134 by way of I/O devices 137 for performing simulation. Such data may include, for example, lithological parameters of formation 100, well survey data, well logging data, pump rate, pump pressure, bottom hole pressure and annulus pressure of wellbore 102, temperatures, viscosity measurements and reservoir volume. Results from simulation may be output by way of I/O devices 137 as instructions for formation stimulation.

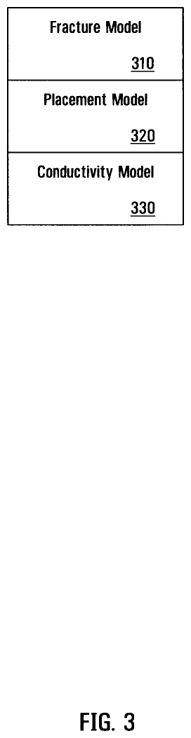

Simulator components at the computing device are shown in FIG. 3. These components may be implemented in hardware or software, or a combination thereof.

Embodiments herein may employ particle-in-cell (PIC) techniques for simulating transport of material within formation 100. The PIC method may be used to forecast spatial distribution of materials present in a system.

PIC algorithms are described in detail in United States patent application publication no. US2015/0060058, the entire contents of which are incorporated herein by reference.

In example embodiments, injected fluids may be modeled as a series of virtual particles. Each particle represents a unit of fluid or solid material, e.g., a fixed volume of fluid or fixed volume of solid proppant. In some embodiments, each virtual particle represents a unit of a specific injected fluid. An injected slurry such as water-proppant slurries may be represented by combinations of particles, e.g. combinations of water particles with solid proppant, in proportions according to the composition of the slurry. Herein, the word “particle” means a virtual particle as a key element in simulation of fluid transport using the Particle-in-Cell computation method, if not stated overwise.

Each particle may have a plurality of associated properties such that tracking of the distribution of the particles throughout formation 100 also provides a distribution of those properties.

Modelling described herein may be performed in a series of time steps. For example, placement of injected fluids may be computed by calculating distribution and velocity fields in a plurality of discrete time steps which collectively make up the entire duration of a pumping operation. The entire duration may include one or more intervals of: pumping in which fluid is actively being pumped into formation 100; shut-in in which pressure of injected fluid within formation 100 is maintained; and compaction in which pressure on injected fluid is released.

Transport of particles may be modeled according to the following relationship, where c(x,y,z) is a function defining physical concentration.

$$\frac{δ c}{δ t} + \frac{\partial c}{\partial x} + \frac{\partial c}{\partial y} + \frac{\partial c}{\partial z} = 0$$

The fluid transport domain (i.e. a fracture 110) is divided into a plurality of discrete elements, namely, grid cells, and for each time step, the above equation is numerically solved at each element. Each grid cell may contain any number of different particles. The volumetric fraction occupied by a particular material in a cell is considered to be the ratio of the sum of volumes of particles of that material to the sum of volumes of all particles in the cell. Particles can move between cells or within the same cell depending on computed velocity field.

As shown in FIG. 3, the simulator includes a fracture network model 310, a fluid placement model 320, and a conductivity model 330. In overview, fracture network model is a numerical model descriptive of propagation of a hydraulic fracture within formation 100 during a stimulation. Fluid placement model 320 is a numerical model defining propagation and location of fluid within the fracture model. Conductivity model 330 is a numerical representation of the effects of injected fluids on the fracture network, namely, propping of fractures, acid etching at fractures, and compaction of fractures by rock bending in order to determine the resulting conductivity distribution of formation 100. Production model 340 is a numerical model describing flow of hydrocarbons through formation 100 to well bore 102 following stimulation.

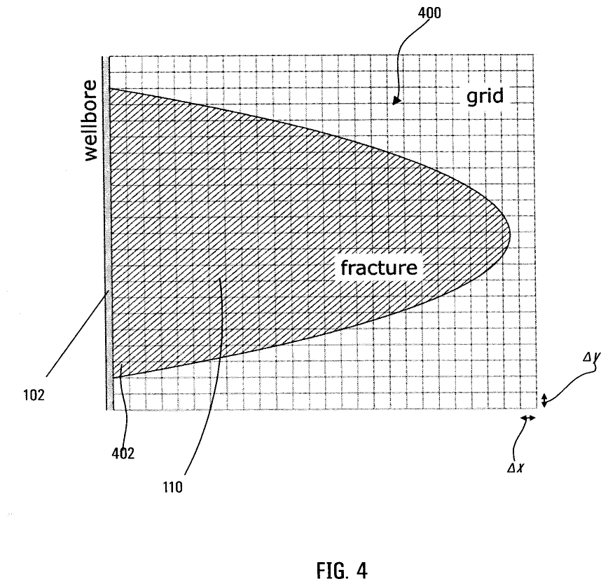

FIG. 4 is a schematic view of a portion of a fracture 110 in formation 100, illustrating a fracture network model.

The position, orientation and dimensions of fracture 110 may be directly measured or inferred from measurements obtained by sensors 132 at the well surface and by sensors 134 in the well bore. The fracture network model numerically simulates, using a fracture generation algorithm, creation or altering of fractures 110 by injection of pressurized fracturing fluid.

The depicted fracture is positioned near an injection port 126 and extends away from the port and into formation 100. The fracture is represented in fracture network model 310 as a two-dimensional matrix of cells 402. Specifically, a two-dimensional grid 400 is plotted along a plane through the fracture. A value is associated with each cell 402 of grid 400, describing the size of the fracture 110 in a dimension perpendicular to the grid 400. As depicted, cells 402 have uniform dimensions Δx and Δy. However, in other embodiments, cells may have differing dimensions. Some cells of grid 400 are boundary cells which abut injection port 126. As will be described in greater detail, each cell may have an associated data record which describes fluids present at the cell, fluid velocity at the cell, and fluid sources at the cell, if applicable.

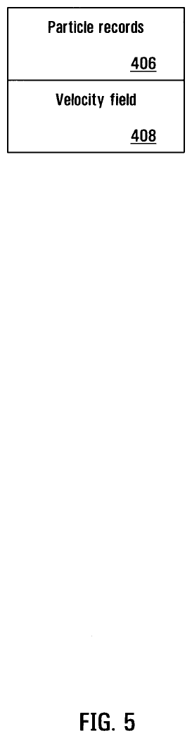

FIG. 5 depicts components of fluid placement model 320. As shown, fluid placement model 320 includes particle records 406 and velocity field records 408.

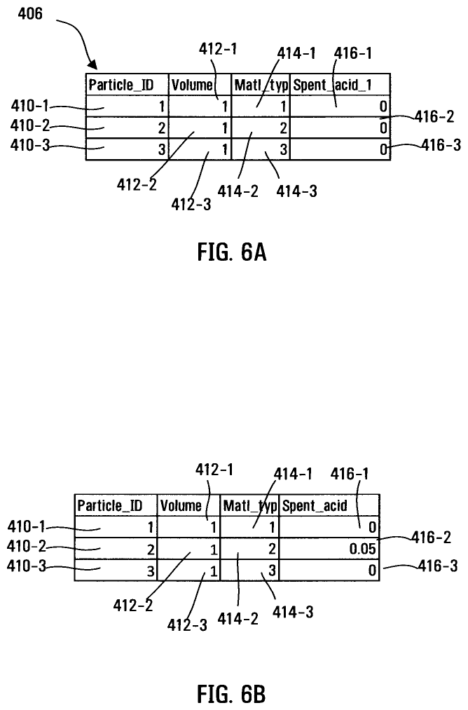

A data record may be associated with each particle in the model. The record may include a plurality of values representing characteristics of the particle. FIGS. 6A-6B depict example data records for three particles. As shown, each data record includes a respective particle identifier 410-1, 410-2, 410-3 (individually and collectively, particle identifiers 410), a respective volume 412-1, 412-2, 412-3 (individually and collectively, volumes 412), a respective particle type 414-1, 414-2, 414-3 (individually and collectively, particle types 414), and a respective spent acid fraction 416-1, 416-2, 416-3 (individually and collectively, spent acid fractions 416).

In the example of FIG. 6A, three particles are shown. A particle with ID “1” has a volume of 1 m³, and is composed of a first material type, e.g., water fluid. A particle with ID “2” has a volume of 1 m³ and is composed of a second material type, e.g. an acid. The spent acid fraction value 416-2 associated with particle 2 is 0.05, indicating that 95% of the acidity of the particle remains. A third particle with ID “3” has a volume of 1 m3 and is composed of a third material type, e.g. proppant. Particles 1 and 3 are not sufficiently acidic to cause significant etching. Spent acid values 416-1, 416-3 associated with particles 1 and 3 are initialized to zero.

Injected materials may include any combination of: water or water-based fluids such as polymer-based gel, with additives such as crosslinkers, defoamers, or friction reducers; proppant slurries such as polymer-based crosslinker gels with ceramic proppant, e.g. intermediate-strength ceramic proppant of API size 20/40; and acidic fluids such as a solution of hydrochloric or other suitable acid in water. Injected materials may further include additives such as corrosion inhibitors, friction reducers, iron control substances and demulsifiers. For stimulation operations which involve injection of both acids and proppants, acid-resistant proppants may be selected. Other injected materials and additives will be apparent to skilled persons. Typically, the pumping of acidic fluid is accompanied by pumping of pre-flash, flush, over-flush of clean water in volumes sufficient to achieve the treatment (fracturing) plan.

Movement of fluid particles through formation 100 is caused by fluid injection and advection due to movement of nearby fluid. Fluid movement is numerically computed cell-by-cell, and fluid movement (e.g. fluid flux) may be approximated using known expressions, as described in United States patent application publication no. US2015/0060058. For example, a parallel plate approximation may be used to model flow through fractures 110. Fluid source terms may be added to the expressions for cells with boundaries at injection ports 126.

Fluid movement may be computed in time-steps during an injection operation, with the total duration of time steps corresponding to the length of the injection operation, plus additional time steps to account for further movement due to residual pressure gradients within the formation 100 after injection is stopped.

As noted, injected fluids may include acids. Such acids may react at rock surfaces as they migrate through formation 100. Etching occurs by reaction of acid with formation rock. The rate of such reactions is influenced by the amount, type and concentration of acidic fluid present.

At each time step, the amount of acid available for reaction in a cell is determined based on “acidic particle” records for particles at the cell (see the definition of Particle-in-Cell method above). For example, the total available acid may be estimated based on the number and type of virtual acidic particles and spent acid value 416 for each virtual acidic particle.

In an example, the amount of etching that occurs to rock surfaces may be defined by the following relationship:

$${w}_{etched} = \frac{w Δ {C}_{A} β}{( 1 - ϕ )}$$

Where w is the fracture width, ΔC_{A} is the change of acid molar concentration due to reaction with rock surface, β is the acid molar dissolving power, and ϕ is the rock porosity.

ΔC_{A} is calculated by numerically solving the following equations:

$$\frac{w}{2} \frac{\partial {C}_{A}}{\partial t} = - {{k}_{r} ( {C}_{w a l l} - {C}_{e q} )}^{m} \\ \frac{w}{2} \frac{\partial {C}_{A}}{\partial t} = - ( {K}_{g} + {u}_{L} ) ( {C}_{M} - {C}_{w a l l} )$$

where C_{wall} is the acid molar concentration at the fracture wall, C_{eq} is the equilibrium acid molar concentration, kᵣ is the reaction rate constant, m is the reaction order, w is the fracture width, K_{g} is a mass transfer coefficient, and u_{L} is the leakoff velocity.

Etching may occur progressively over time. Thus, for each time step of a pumping operation, etching within a cell 402 may be estimated, and the width of fracture 110 in that cell may be updated to account for the etching.

Reaction of acid with formation rock may consume the acid and produce non-acidic reaction products. In some embodiments, the composition and volume of fluid in a cell 402 may be assumed constant notwithstanding occurrence of acid reactions. In other words, volume 412 and fluid fractions 414 may be treated as unchanged by etching reactions. However, consumption of acid may be tracked with a spent acid quantity 416 corresponding to each fluid fraction 414. Spent acid 416 may be incremented at each time step as acid associated with a virtual particle is consumed, e.g. as described above.

FIG. 6A shows a particle record 406 at the beginning of a time step. The particle contains an acid component, namely, fluid 2. At the beginning of the time step, none of the acid component has been consumed by etching reactions.

FIG. 6B shows the particle record 406 at the end of the time step. As a result of etching reaction during the time step, 5% of the acid is calculated to be spent. Accordingly, spent acid value 416 is incremented from 0 to 0.05.

At subsequent time steps, the spent acid fraction may reduce the rate of etching. For example, in the above example, changes in spent acid values 416 and movement of acidic particles may alter the acid concentration at the fracture wall, i.e. C_{wall}. The spent acid fraction may progressively increase at each time step as additional acid is consumed by etching.

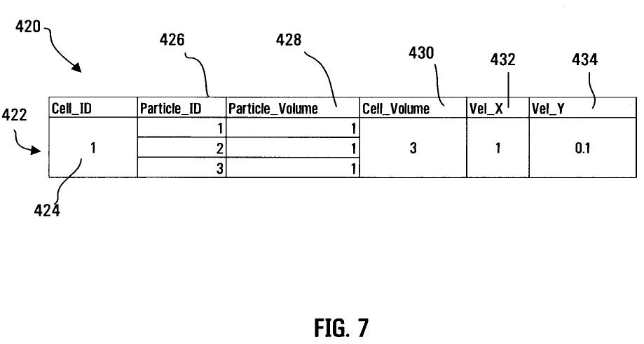

At each time step, fluid particles in each cell 402 and fluid velocities in each cell 402 are recorded. FIG. 7 depicts an example data structure 420 including a record for each cell 402 with fluid particle and velocity records. As depicted, a record 422 is maintained for each cell 402. The cell record 422 includes a cell ID 424, a particle ID 426 and a corresponding particle volume 428 for each particle present at the cell, a cell volume 430, a velocity value 432 in the X direction and a velocity value 432 in the Y direction. The collection of velocity values 432, 434 may be referred to as a velocity field.

Values of particle ID 426 in data structure 420 correspond to values of particle ID 410 in data record 408. Corresponding properties of particles may be directly stored in data record 420 or, as depicted, stored in data record 408 and referenced in data structure 420 by way of the particle ID. This sequence demonstrates how the Particle-in-Cell method works for every time step.

At the conclusion of fluid placement modeling, data structure 420 reflects final positions (i.e. placement) of injected fluids.

Suitable fluid placement modeling may be performed using Kinetix® and FracCADE® (version 7.4), available from Schlumberger.

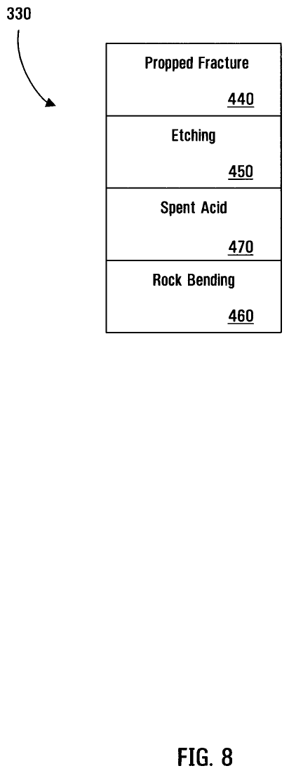

FIG. 8 depicts components of conductivity model 330 in greater detail. Conductivity model 330 includes a fracture propping component 440, an etching component 450, a rock bending component 460 and a spent acid component 470.

Fracture propping component 440 models deformation of proppant pack under formation stress following release of injection pressure, and thus, estimates final aperture width of fractures at locations where proppant is placed.

Distribution of proppant is determined according to final particle positions, as computed using fluid placement model 320. The portion of formation 100 surrounding a fracture 110 is considered as two elastic bodies on opposing sides of the fracture 110.

Fracture 110 is divided into a grid of cells, as described above with reference to FIG. 4. For each cell at which proppant is present, the proppant is considered to fill space between the rock surfaces. Upon release of the injection stress, apertures are approximated to at close to a final aperture width as a function of stress in formation 100 and the stress modulus of the proppant and the rock of the formation. Details of such calculations are disclosed, for example, in United States patent application publication no. US2015/0060058.

Etching component 450 models changes in aperture width due to acid etching of rock at fracture boundaries.

Rock etching and proppant placement in fracture 110 may be non-uniform. Rock bending component 460 accounts for deflection of rock in formation 100 around propped or etched sections of fractures, which may be referred to as compaction.

Calculations performed by rock bending component 460 are done using grid 400 of cells 402 described above with reference to FIG. 4. Rock bending component 460 identifies cells 402 either as propped cells, in which opposing walls of a fracture are held apart by a proppant pack, channel cells, in which the space between walls is not filled with proppant, but in which bending of rock is not sufficient for the walls to contact one another, or pinchpoint cells, in which walls contact one another and occlude flow.

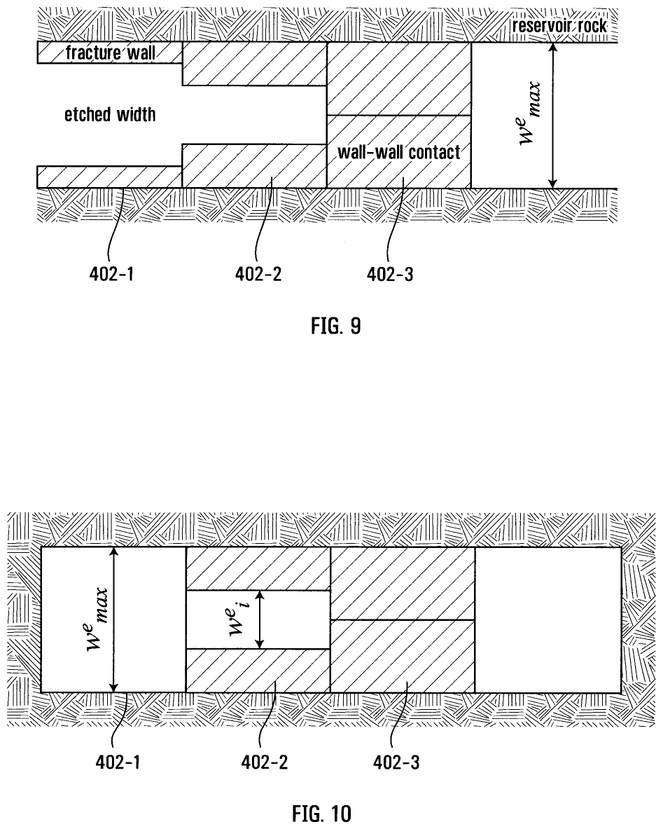

FIG. 9 depicts a set of three cells 402-1, 402-2, 402-3 in which acid etching has occurred. Specifically, fracture wall 462 has been etched in cells 402-1 and 402-2, thereby widening the aperture sizes in those cells.

As shown in FIG. 10, rock bending component computes a maximal aperture width, Wₘₐₓ across fracture 110, namely, the maximum aperture calculated for a cell within the fracture. At each cell, a computed etched width wᵢ^{e} is subtracted from the maximal aperture width to yield a thickness of rock remaining in the fracture area. This portion of rock may result from non-uniform etching along fracture 110. For a given cell 402, this rock portion may be referred to as a rock pillar and its and width may be referred to as a rock pillar width wᵢ^{rP}. Rock pillar width is determined according to the following relationship:

wᵢ^{RP}=wₘₐₓ^{e}−wᵢ^{e}

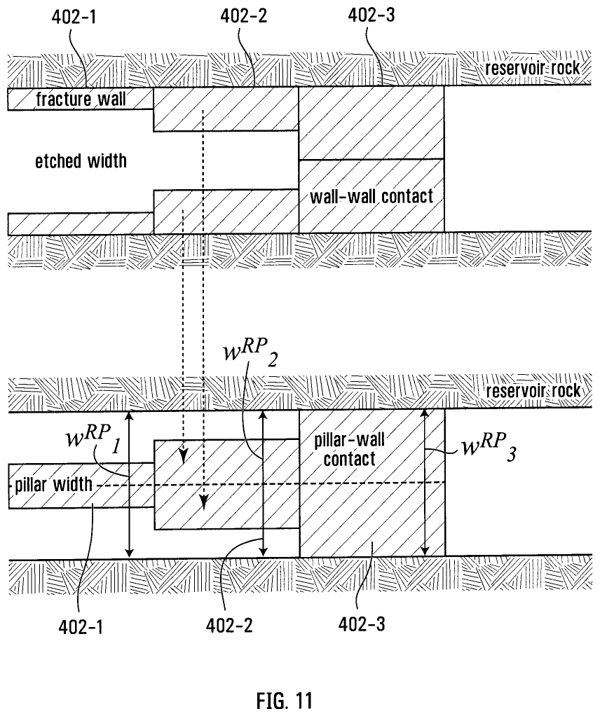

The computed rock pillar for each cell 402 is virtually moved to the center of the cell, as shown in FIG. 11. That is, although the rock pillar width is made up of rock sections at the fracture walls, for purposes of bending calculations, the cells may be treated as having central segments of rock of thickness equivalent to the rock pillar thickness wᵢ^{rp}

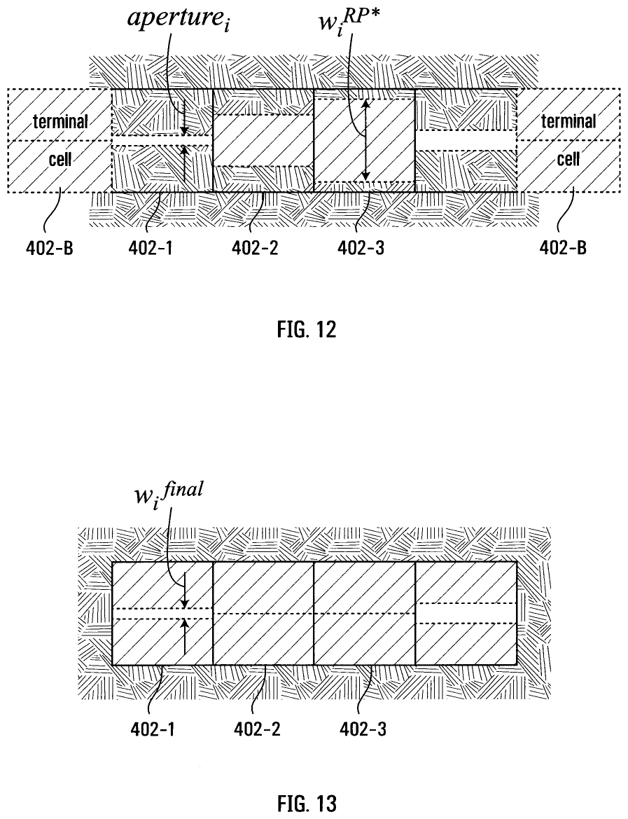

Boundary conditions are assigned to cells at ends of fracture 110. In an example, the boundary conditions may defined as extra cells of intact rock 402-B at each end of the grid 400, as shown in FIG. 12.

Compaction of the rock pillars is then computed using the approach described above for compaction of proppant. Specifically, compaction of each rock pillar is computed based on the stress modulus of the rock and the formation stress.

Compaction may be computed in a series of time steps. At each time step, rock bending is calculated based on balancing formation stress with elastic properties of the rock, namely, the stress modulus and Poisson's ratio of the rock. Adjacent and boundary cells of grid 400 are treated as a system. That is, bending of rock in a cell depends on the states of the adjacent cells. At a particular time step, if stress in the rock based on predicted bending and the positions of adjacent cells does not balance formation stress, further bending of the rock may be predicted and bending calculations then repeated based on the new predicted state of the rock. Compaction calculations stop when no further bending is predicted at a given time step, and the resulting state of rock in each cell 402 is taken as the final compacted state.

This calculation results in a aperture for each cell, named apertureᵢ.

Actual compacted rock pillar widths are then computed as follows, where σ_{c} is the compaction stress and M is the longitudinal stress modulus of the rock:

wᵢ^{RP*}=wᵢ^{RP}·(1−σ_{c}/M), if wᵢ^{RP*}<apertureᵢwᵢ^{RP*}=wᵢ^{RP}, otherwise

In other words, the compacted rock pillar width is reduced by the based on stress applied to the rock only if the result is less than the computed aperture. An example of this calculation is illustrated in FIG. 12.

Final etched widths wᵢ^{final} are calculated by subtracting pillar widths from apertures of each cell:

wᵢ^{final}=apertureᵢ−wᵢ^{RP*}

If this results in negative final width for any cell, the width for that cell is instead set to zero. FIG. 13 depicts final etched widths for cells 402-1, 402-2, 402-3.

In some embodiments, rock bending may account for both bending in acid-etched areas and bending around proppant packs in fractures 110.

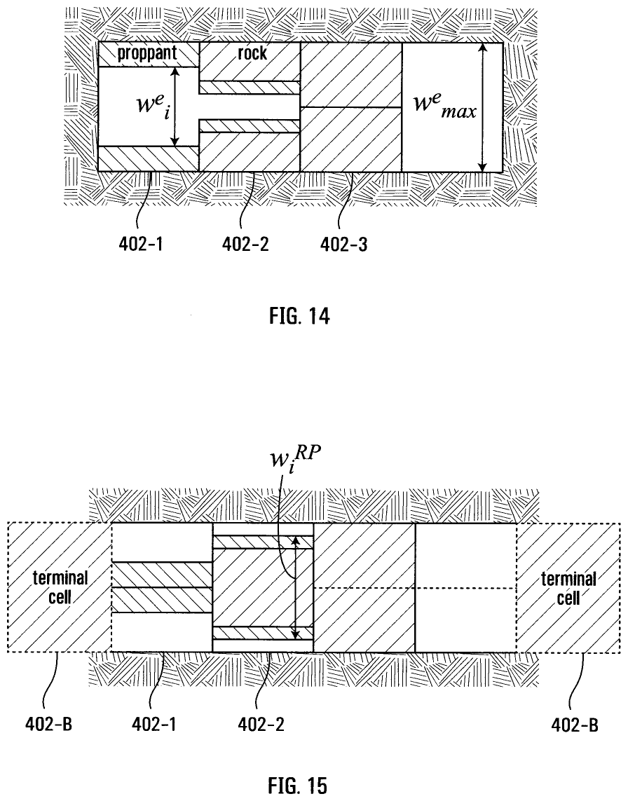

Modeling of compaction at cells with proppant packs is depicted in FIGS. 14-15.

As shown in FIG. 14, cells may have an opening width wᵢ^{e} between opposing rock faces and any proppant packs. A fracture 110 may have a maximal width of wₘₐₓ^{e}.

Proppant is considered as part of the rock pillar in any cell. Thus, the size of proppant-rock pillar at a cell is calculated as the difference between the fracture maximal width opening width wₘₐₓ^{e} at that cell and the actual opening width wᵢ^{e} at that cell.

As shown in FIG. 15, boundary conditions are defined, e.g. in the form of terminal cells of solid rock. The computed rock-proppant pillars are virtually shifted to the center of each cell.

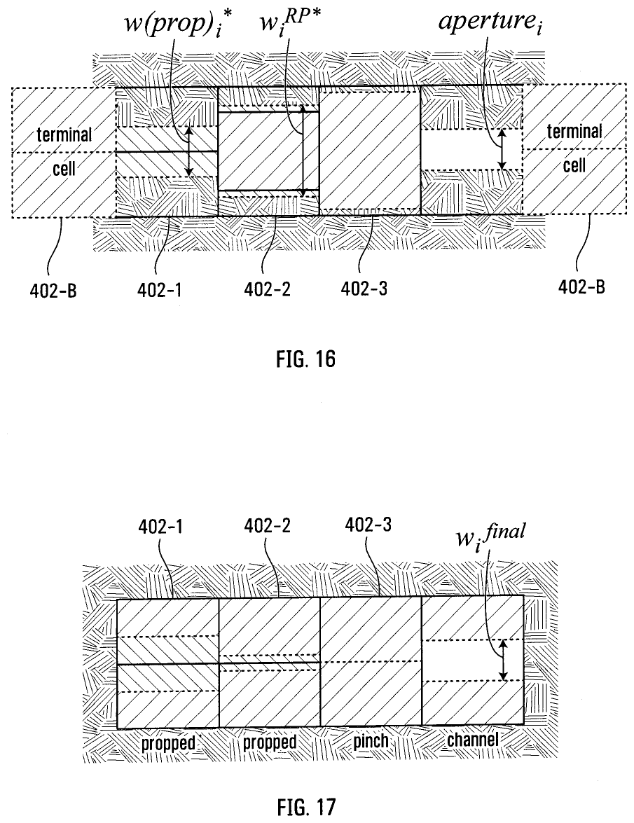

Compaction is then modeled for the rock-proppant pillars in the same manner as described above with reference to acid-etched rock pillars. Specifically, compacted widths for the pillars are computed as follows, as depicted in FIG. 16:

wᵢ^{RP*}=wᵢ^{RP}·(1−σ_{c}/M), if wᵢ^{RP*}<apertureᵢwᵢ^{RP*}=wᵢ^{RP}, otherwise

Where σ_{c} is the portion of the formation stress applied to the pillar and M is the stress modulus of the formation rock.

Final etched widths wᵢ^{final} are calculated by subtracting pillar widths from apertures of each cell:

wᵢ^{final}=apertureᵢ−wᵢ^{RP*}

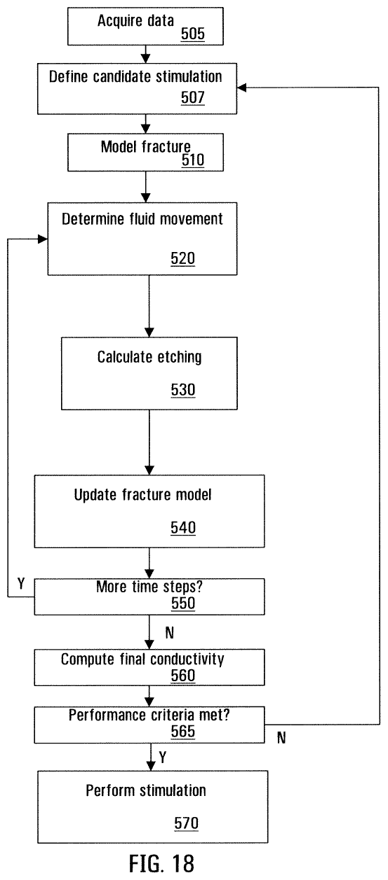

Any negative widths are instead set to zero. Final compacted widths are depicted in FIG. 17.

FIG. 18 depicts an example stimulation process 500 based on simulation.

At block 505, data is acquired from sensors at formation 100. Specifically, measurements are obtained from sensors 132, 134 at formation 100 and within wellbore 102. As noted, measurements may include, for example, lithological parameters of formation 100, well survey data, well logging data, pump rate, pump pressure, bottom hole pressure and annulus pressure of wellbore 102, temperatures, viscosity measurements and reservoir volume.

At block 507, a candidate stimulation operation is defined. The stimulation design includes a plurality of stages, each defining a duration, pumping rate at which fluid is to be injected through wellbore 102, one or more types and of acid to be injected and corresponding concentrations, and optionally, one or more proppant types to be injected and corresponding concentrations. The water fluid before and after the acid (pre-flush, flush, over-flush) is another type of fluid to be defined in a candidate stimulation.

At block 510, a model is created of fractures 110 within formation 100. The model is created using fracture modelling component 310 (FIG. 3). The measurements obtained at block 505 and candidate stimulation design defined at block 507 are used to create an approximation of fracture geometry within the formation. A grid is overlaid on the geometry approximation, and defines a set of discrete cells of finite dimensions. The grid may be two-dimensional, and a value may be associated with each grid cell describing fracture width at each cell. Modeling steps may then be performed on a cell-by-cell basis.

Once the fracture model is defined, transport of fluid into formation 100 through fractures 110 is simulated in time steps.

At block 520, transport of fluid through fractures 110 of formation 100 is simulated using placement model 320. Transport is modeled using PIC techniques. Flow through each cell may be computed using equations for flow between flat plates, for a specific defined time step. Boundary cells at which fluid is injected may be modeled using boundary conditions to represent injection as a fluid source.

Transport calculations performed at block 520 define a position for each fluid particle, namely, a cell 402 in which each fluid particle is located. Transport calculations also define fluid velocities at each cell 402. The positions of particles and velocity in each cell are recorded in a data structure 420 and are used for transport calculations at subsequent time steps.

At block 530, etching of rock surfaces by acid within the stimulation fluid is computed. Based on position of acids, as well as the type, amount and concentration of acid within each cell, the rate of etching reactions is determined. Based on the computed rate, an adjusted fracture width is computed for each cell.

The amount of acid used up in etching reactions is tracked and spent acid is recorded for each fluid particle.

At block 540, the previously-created model of fractures 110 in the formation is updated. New fracture widths are saved for cells at which etching occurs.

At block 550, it is determined if all time steps have been completed. If not, process 500 returns to 520 to repeat the fluid transport calculations for a new time step. If all time steps have been completed, i.e., if the time steps cumulatively make up the total duration of a pumping operation, the process moves to block 560.

At block 560, the post-stimulation conductivity distribution is computed, using final positions of particles from data structure 420.

Cells 402 with proppant packs are identified based on the final placement of proppant particles from data structure 420. The widths of such proppant packs are computed, based on fracture width after any etching by acids.

Likewise, the total etched width of fractures 110 is determined for each cell.

Rock bending calculations are performed to determine the degree of compaction around proppant packs and into etched areas. A rock pillar or rock-proppant pillar thickness is calculated for each cell, and corresponding pillars are defined. Compaction is then simulated to determine the final fracture width after release of injection pressure.

Once fracture width distribution is calculated, corresponding conductivity values may be computed. In an example, flow through channel cells may be approximated using the cubic law, namely:

(k_{f}w=wᵢ³/12)

Where k_{f} is permeability and the product of permeability and fracture width, i.e., kⱼw is referred to as fracture conductivity.

The resulting conductivity distribution may be evaluated to ascertain the predicted success of the stimulation operation. For example, a total conductivity may be computed for all cells 402 in formation 100. Additionally or alternatively, a median conductivity may be computed. These quantities may be compared to threshold values to determine whether the stimulation meets performance criteria.

In some embodiments, post-stimulation conductivity predicted by the stimulation may be compared to estimates of pre-stimulation conductivity. Predicted performance of the stimulation operation may be evaluated, for example, based on a ratio or absolute increase of conductivity. Additionally or alternatively, predicted performance may be evaluated based on a forecast of production. For example, simulation may be performed to estimate cumulative hydrocarbon production volume, production rate over time, or both. Production simulation may be based on modeling fluid transport through the formation using particle-in-cell techniques as described above, except that while fluid is being pumped out of wellbore 102, pressure gradients in formation 100 will tend to draw fluids toward wellbore 102. Predicted production values may be compared to threshold values, or results from multiple stimulation designs may be compared against one another.

At block 565, it is determined if the predicted conductivity meets performance criteria. If not, the process returns to block 507, the candidate stimulation operation is revised and the process repeats.

If the conductivity simulation predicts adequate performance, the candidate stimulation operation is accepted as the final at block 570, the modeled stimulation operation may be implemented at wellbore 102. That is, stimulation may be performed with the sequence of injection fluids at the pressure, quantity, duration and location prescribed in the simulation. Alternatively, if the conductivity predicted by the simulation is inadequate, the stimulation design may be altered, and simulation may be repeated.

Embodiments disclosed herein may allow for precise determination of conductivity of a formation after a stimulation. For example, by comparison to models which take into account only one of acid etching or proppant injection, or by comparison to models which do not track the spent acid over time, conductivity predictions may be improved. Performance assessment for candidate stimulation designs may likewise be improved, leading to better stimulation designs.

### Examples

The following examples are provided for further illustration of methods and systems disclosed herein, and are not limiting of the invention. Measurement data of an example formation are shown in tables I-II below. As shown, the measurements are associated with zones of the formation, defined in terms of depth along a wellbore.

Example 1 illustrates the steps of simulation for an acid transport to a fracture at the pressure above the fracturing pressure of a treated formation. The virtual particles within the Particle-in-Cell method describe the transport of acidic fluid and water fluid within the computation domain. The Tables summarize the main inputs and outputs for every step of invention embodiments. The limestone in this example multizonal formation is prone to fracturing and acidizing (acid fracturing treatment).

TABLE I
Formation measurements

| | | Top | Gross | | Reservoir |
|---|---|---|---|---|---|
| | Zone | Depth | Height | Rock | Pressure |
| | Name | (m) | (m) | Type | (MPa) |
| 1 | Zone 1 | 8200 | 300 | Shale | 452.5 |
| 2 | Zone 2 | 8500 | 25 | Limestone | 452.5 |
| 3 | Zone 3 | 8525 | 50 | Limestone | 452.5 |
| 4 | Zone 4 | 8575 | 25 | Limestone | 452.5 |
| 5 | Zone 5 | 8600 | 328 | Shale | 452.5 |

TABLE II
Formation measurements

| | Minimal | | | | |
|---|---|---|---|---|---|
| | Horizontal | | | Young's | |
| | Stress | Permeability | Porosity | Modulus | Temperature |
| | (MPa) | (mD) | (%) | (MPa) | (° C.) |
| 1 | 835.0 | 0.0001 | 1.00 | 4200 | 217.4 |
| 2 | 851.250 | 0.1000 | 10.00 | 4200 | 220.1 |
| 3 | 461.7 | 0.1000 | 10.00 | 4200 | 220.7 |
| 4 | 858.75 | 0.1000 | 10.00 | 4200 | 221.3 |
| 5 | 876.404 | 0.0001 | 1.00 | 4200 | 224.2 |

Based on the measurements, four example candidate treatments are shown in tables III-VI. As shown, each candidate treatment has multiple steps, defined as pre-flush, acid, overflush and flush. For each step, the candidate treatment defines a pump volumetric rate (m³/min), fluid type (acid or water) and injected fluid volume for the step.

TABLE III
Candidate treatment 1:

| | | Pump | | Fluid |
|---|---|---|---|---|
| | Step | Rate | | Volume |
| | name | m³/min | Fluid | m³ |
| 1 | Pre-flush | 1.59 | Water | 3.74 |
| 2 | Acid | 1.59 | HCl 28 | 4.59 |
| 3 | Overflush | 1.59 | Water | 1.90 |
| 4 | Flush | 1.59 | Water | 7.94 |

TABLE IV
Candidate treatment 2:

| | | Pump | | Fluid |
|---|---|---|---|---|
| | Step | Rate | | Volume |
| | name | m³/min | Fluid | m³ |
| 1 | Pre-flush | 1.59 | Water | 13.56 |
| 2 | Acid | 1.59 | HCl 28 | 16.24 |
| 3 | Overflush | 1.59 | Water | 2.62 |
| 4 | Flush | 1.59 | Water | 7.94 |

Table IV: Candidate treatment 2

TABLE V
Candidate treatment 3:

| | | Pump | | Fluid |
|---|---|---|---|---|
| | Step | Rate | Fluid | Volume |
| | name | m³/min | Name | m³ |
| 1 | Pre-flush | 1.59 | Water | 20.53 |
| 2 | Acid | 1.59 | HCl 28 | 24.40 |
| 3 | Overflush | 1.59 | Water | 2.88 |
| 4 | Flush | 1.59 | Water | 7.94 |

TABLE VI
Candidate treatment 4

| | | Pump | | Fluid |
|---|---|---|---|---|
| | Step | Rate | Fluid | Volume |
| | name | m³/min | Name | m³ |
| 1 | Pre-flush | 1.59 | Water | 2.88 |
| 2 | Acid | 1.59 | HCl 28 | 34.02 |
| 3 | Overflush | 1.59 | Water | 3.15 |
| 4 | Flush | 1.59 | Water | 7.94 |

Fracture propagation data (i.e., fracture half-length) calculated for each candidate treatment 1-4 is shown in Table VII. The fracture propagation data is calculated using the Particle-in-Cell method to determine the position and concentration of all fluids injected into the fracture, including acidic fluids. The longest version of fracture among the simulated candidates belong to candidate IV with the biggest amount of treatment fluid volume.

TABLE VII
Fracture half-length

| | | Fracture |
|---|---|---|
| | Treatment | half-length |
| | name | m |
| 1 | Treatment 1 | 29.77 |
| 2 | Treatment 2 | 85.82 |
| 3 | Treatment 3 | 117.16 |
| 4 | Treatment 4 | 147.39 |

Acid etching data computed at the same time is shown in table VIII. Spent acid is tracked using the particle-in-cell method and etched width is shown as an average over the domain of the simulation.

TABLE VIII
Etching width of fracture

| | | Average |
|---|---|---|
| | | etched |
| | Treatment | width |
| | name | mm |
| 1 | Treatment 1 | 2.53 |
| 2 | Treatment 2 | 10.38 |
| 3 | Treatment 3 | 5.32 |
| 4 | Treatment 4 | 6.39 |

Compaction of rock based on the calculated etched width is reflected in table IX. Now the etched width (after compaction) is more realistic than for the previous step of computation the etching for fracture walls. Compaction is simulated using the rock pillars defined from the etched width distribution and is shown as an average value over the fracture. Known compacted width allows calculating the final conductivity of a fracture in every grid cell in every version of treatment.

TABLE IX
Compacted width

| | | Average |
|---|---|---|
| | | compacted |
| | | fracture |
| | Treatment | width |
| | name | mm |
| 1 | Treatment 1 | 0.59 |
| 2 | Treatment 2 | 2.39 |
| 3 | Treatment 3 | 1.24 |
| 4 | Treatment 4 | 1.33 |

Table X shows the predicted fluid conductivity corresponding to the compacted width distribution, shown as an average value over the fracture. Predicted fluid conductivity may be compared with the target conductivity for estimating if the goal of acidic treatment was achieved or not.

TABLE X
Predicted conductivity

| | | Average |
|---|---|---|
| | | fracture |
| | Treatment | conductivity |
| | name | mD_{°}x_{°}m |
| 1 | Treatment 1 | 1,456 |
| 2 | Treatment 2 | 10,980 |
| 3 | Treatment 3 | 1,785 |
| 4 | Treatment 4 | 2,004 |

The performance target for the candidate treatments was an average conductivity of about 5,000 mD° x° m after acidic stimulation. Treatment 2 had the highest predicted conductivity among the candidate treatments and was predicted to meet the performance target. Treatment 2 was selected as the final treatment, to be applied at the formation.

Example 2 illustrates the main steps of acidic stimulation as shown in Example 1, wherein the treatment fluid is a viscous acid fluid that carries portions of proppant into the fracture. The proppant is added to the treatment fluid in a pulse mode. This type of hydraulic fracturing is known as a technology of channel fracturing HiWAY® developed by Schlumberger Company (U.S.) and widely used for layers of sandstone. The proppant concentration for proppant-rich pulses was close to 360 m³/kg, and these proppant-rich pulses are followed by “clean” stages of the same duration (only acid without proppant). The proppant was acid-resistant solid particles CarboProp® Light with mesh size 20/40 and relative density 2.64. In this case, Particle-in-Cell method deals with several types of “virtual particles” (gelled acid, proppant, water)—see the identification table in FIGS. 6A-6B. The channel fracturing produces the proppant pillars with open channel between them. Wall etching occurs mainly in the open (channelled) pathways.

According to invention, compaction of proppant pillars under the stress of formation (the same type of formation described in Tables I-II of Example 1) reduces the actual width of fracture. The target level of average conductivity for the propped-and-acidized fracture (e.g., 5,000 mD° x° m) was achieved in one of the simulated candidate treatment, and then the actual hydraulic fracturing operation was performed.

The particular embodiments disclosed above are illustrative only, as the present disclosure may be modified and practiced in different but equivalent manners apparent to one having ordinary skill in the art and having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein.

What is claimed is:

1. A method of acid stimulation of fluid production from a well in a formation, comprising:
a. obtaining measurements of formation characteristics;
b. defining a plurality of candidate stimulation treatments comprising injection of an acidic fluid;
c. for each one of the candidate simulation treatments:
i. based on the measurements, simulating fracture propagation in the formation, induced by pressurized fluid injection, the simulating comprising defining grid cells representing a fracture;
ii. simulating transport of an injected acidic fluid through the formation, wherein the simulating transport comprises tracking movement of units of the acidic fluid between ones of the grid cells;
iii. simulating etching of rock in the fracture to obtain a model of an etched fracture comprising a plurality of rock pillars representing non-uniform etching in the grid cells;
iv. simulating compaction of rock in the formation based on an etched fracture size for each one of the grid cells, to obtain a compacted fracture size associated with each one of the grid cells; and
v. calculating a predicted fluid conductivity associated with the candidate stimulation treatment, based on the simulating;
d. defining a final stimulation treatment based on one of the candidate stimulation treatments and the predicted fluid conductivity; and
e. injecting the acidic fluid into the formation according to the final stimulation treatment.

2. The method of claim 1, wherein each candidate stimulation treatment comprises a plurality of stages, each having a defined duration, pumping rate, acid type and concentration and proppant type and concentration.

3. The method of claim 1, wherein the simulating fracture propagation is based on a candidate stimulation treatment, formation properties, and the pressure of injected acidic fluid.

4. The method of claim 1, wherein the simulating fracture propagation comprises calculating a fracture size for each of the grid cells.

5. The method of claim 1, wherein the simulating transport of an injected acidic fluid comprises using a particle-in-cell method with the grid cells.

6. The method of claim 5, further comprising, for each of the candidate stimulation treatments, simulating transport of a proppant through the fracture using a particle-in-cell method.

7. The method of claim 6, further comprising, for each of the candidate stimulation treatments, simulating compaction of rock in the formation around the proppant.

8. The method of claim 1, wherein the simulating compaction of rock comprises calculating compression of rock pillars at each one of a plurality of the grid cells.

9. The method of claim 1, further comprising, for each of the candidate stimulation treatments, simulating the consumption of acid by etching of rock.

10. The method of claim 1, wherein the simulating transport comprises maintaining data records corresponding to units of fluid.

11. The method of claim 10, wherein the simulating transport comprises tracking positions of the units of fluid at ones of the grid cells in a plurality of time steps.

12. The method of claim 10, further comprising, for each of the candidate stimulation treatments, tracking a consumed portion of acid in ones of the data records corresponding to units of fluid.

13. A system for acid stimulation of fluid production from a well in a formation, comprising:
a. a plurality of sensors for measuring characteristics of the formation;
b. a computing device comprising a processor and a computer-readable storage;
c. computer-readable instructions stored on the computer-readable storage, for simulating a plurality of candidate stimulation treatments comprising injection of an acidic fluid, the computer-readable instructions comprising:
i. a fracture propagation model for simulating fracture propagation induced by pressurized fluid injection in the formation, by defining grid cells representing a fracture;
ii. a transport model for simulating transport of an injected acidic fluid through the formation by tracking movement of units of the acidic fluid between ones of the grid cells;
iii. an etching model for simulating etching of rock in the fracture to obtain a representation of an etched fracture comprising a plurality of rock pillars from non-uniform etching in the grid cells;
iv. a rock-bending model for simulating compaction of rock in the formation based on an etched fracture size for each one of the grid cells, to obtain a compacted fracture size associated with each one of the grid cells;
v. instructions for evaluating a predicted fluid conductivity associated with each of the candidate stimulation treatments, based on the simulating, wherein one of the candidate simulation treatments is defined as a final simulation treatment in response to the predicted fluid conductivity meeting performance criteria.

14. The system of claim 13, wherein each candidate stimulation treatment comprises a plurality of stages, each having a defined duration, pumping rate, acid type and concentration and proppant type and concentration.

15. The system of claim 13, wherein the simulating fracture propagation comprises defining a formation model based on measurements from the plurality of sensors.

16. The system of claim 13, wherein the rock bending model includes instructions for simulating bending of rock around proppant.

17. The system of claim 13, wherein the simulating compaction of rock comprises calculating compression of a rock pillar at each one of a plurality of the grid cells.

18. The system of claim 13, wherein simulating etching comprises simulating consumption of acid by etching of rock.

19. The system of claim 13, wherein the simulating transport comprises a particle-in-cell method.

20. The method of claim 13, wherein the simulating consumption of etching comprises maintaining a data records corresponding to units the acidic fluid, the data records including a proportion of spent acid.

21. The method of claim 13, wherein the simulating transport comprises tracking positions of the units of fluid at ones of the grid cells in a plurality of time steps.

22. A method of acid stimulation of fluid production from a well in a formation, comprising:
a. obtaining measurements of formation characteristics;
b. defining a plurality of candidate stimulation treatments comprising injection of a slurry comprising acidic fluid and proppant;
c. for each of the plurality of candidate stimulation treatments:
i. based on the measurements, simulating fracture propagation and fluid-proppant slurry transport in the formation, using a particle-in-cell method;
ii. simulating etching of rock in the fracture to obtain a model of an etched fracture comprising a plurality of rock pillars representing non-uniform etching in the grid cells;
iii. simulating compaction of rock in the formation based on an etched fracture size for each one of the grid cells, to obtain a compacted fracture size associated with each one of the grid cells; and
iv. calculating a predicted fluid conductivity associated with the candidate stimulation treatment, based on the simulating;
d. defining a final stimulation treatment based on one of the candidate stimulation treatments and the predicted fluid conductivity; and
e. injecting the acidic fluid with proppant into the formation according to the final stimulation treatment.
